(19) United States
(12) Patent Application Publication
(10) Pub. No.: US 2025/0331194 A1
(43) Pub. Date: Oct. 23, 2025

(54) FERROELECTRIC CAPACITOR STRUCTURE

(71) Applicant: Powerchip Semiconductor Manufacturing Corporation, Hsinchu (TW)

(72) Inventors: Wei-Teng Hsu, Hsinchu (TW); Yu-Rui Chen, Hsinchu (TW); Wei-Jen Chen, Hsinchu (TW); Chee-Wee Liu, Taipei City (TW)

(73) Assignee: Powerchip Semiconductor Manufacturing Corporation, Hsinchu (TW)

(21) Appl. No.: 18/663,120

(22) Filed: May 14, 2024

(30) Foreign Application Priority Data
Apr. 19, 2024 (TW) 113114819

(51) Int. Cl. H10B 53/30

(52) U.S. Cl. CPC H10B 53/30

(57) ABSTRACT

A ferroelectric capacitor structure including a first electrode, a second electrode, a first ferroelectric material layer, and a first nucleation layer is provided. The second electrode is located on the first electrode. The first ferroelectric material layer is located between the first electrode and the second electrode. The first nucleation layer is in contact with the first ferroelectric material layer. The material of the first nucleation layer is beta-tungsten (B-W).

### CROSS-REFERENCE TO RELATED APPLICATION

This application claims the priority benefit of Taiwan application serial no. 113114819, filed on Apr. 19, 2024. The entirety of the above-mentioned patent application is hereby incorporated by reference herein and made a part of specification.

### BACKGROUND

### Technical Field

The invention relates to a semiconductor structure, and particularly relates to a ferroelectric capacitor structure.

### Description of Related Art

A typical ferroelectric capacitor includes two electrodes and a ferroelectric material layer between the two electrodes. The size of the ferroelectric capacitor is very small compared to other capacitors. However, how to improve the remanent polarization of the ferroelectric material layer in the ferroelectric capacitor is the goal of continuous efforts.

### SUMMARY

The invention provides a ferroelectric capacitor structure, which can effectively improve the remanent polarization of the ferroelectric material layer.

The invention provides a ferroelectric capacitor structure, which includes a first electrode, a second electrode, a first ferroelectric material layer, and a first nucleation layer. The second electrode is located on the first electrode. The first ferroelectric material layer is located between the first electrode and the second electrode. The first nucleation layer is in contact with the first ferroelectric material layer. The material of the first nucleation layer is beta-tungsten (β-W).

According to an embodiment of the invention, in the ferroelectric capacitor structure, the first nucleation layer may be located between the first ferroelectric material layer and the first electrode.

According to an embodiment of the invention, the ferroelectric capacitor structure may further include a second nucleation layer. The second nucleation layer may be located between the first ferroelectric material layer and the second electrode. The second nucleation layer may be in contact with the first ferroelectric material layer. The material of the second nucleation layer may be β-W.

According to an embodiment of the invention, the ferroelectric capacitor structure may further include a second ferroelectric material layer and a second nucleation layer. The second ferroelectric material layer is located between the first ferroelectric material layer and the second electrode. The second nucleation layer may be located between the first ferroelectric material layer and the second ferroelectric material layer. The second nucleation layer may be in contact with the first ferroelectric material layer and the second ferroelectric material layer. The material of the second nucleation layer may be β-W.

According to an embodiment of the invention, the ferroelectric capacitor structure may further include a third nucleation layer. The third nucleation layer may be located between the second ferroelectric material layer and the second electrode. The third nucleation layer may be in contact with the second ferroelectric material layer. The material of the third nucleation layer may be β-W.

According to an embodiment of the invention, in the ferroelectric capacitor structure, the first nucleation layer may be located between the first ferroelectric material layer and the second electrode.

According to an embodiment of the invention, the ferroelectric capacitor structure may further include a second ferroelectric material layer and a second nucleation layer. The second ferroelectric material layer is located between the first ferroelectric material layer and the first electrode. The second nucleation layer may be located between the first ferroelectric material layer and the second ferroelectric material layer. The second nucleation layer may be in contact with the first ferroelectric material layer and the second ferroelectric material layer. The material of the second nucleation may be β-W.

According to an embodiment of the invention, the ferroelectric capacitor structure may further include a second ferroelectric material layer. The second ferroelectric material layer is located between the first ferroelectric material layer and the second electrode. The first nucleation layer may be located between the first ferroelectric material layer and the second ferroelectric material layer. The first nucleation layer may be in contact with the second ferroelectric material layer.

According to an embodiment of the invention, in the ferroelectric capacitor structure, the ferroelectric capacitor structure may be a planar structure or a cylinder structure.

According to an embodiment of the invention, in the ferroelectric capacitor structure, the material of the first electrode may include metal.

According to an embodiment of the invention, in the ferroelectric capacitor structure, the material of the first electrode may include β-W, alpha-tungsten (α-W), platinum (Pt), titanium (Ti), titanium nitride (TiN), aluminum (Al), tungsten nitride (WN), ruthenium (Ru), ruthenium oxide (RuO), tantalum (Ta), nickel (Ni), cobalt (Co), copper (Cu), silver (Ag), or gold (Au).

According to an embodiment of the invention, in the ferroelectric capacitor structure, the material of the second electrode may include metal.

According to an embodiment of the invention, in the ferroelectric capacitor structure, the material of the second electrode may include β-W, α-W, platinum, titanium, titanium nitride, aluminum, tungsten nitride, ruthenium, ruthenium oxide, tantalum, nickel, cobalt, copper, silver, or gold.

According to an embodiment of the invention, in the ferroelectric capacitor structure, the material of the first ferroelectric material layer may include hafnium oxide (HfO₂), zirconium oxide (ZrO₂), or a combination thereof.

According to an embodiment of the invention, in the ferroelectric capacitor structure, the hafnium oxide may be undoped hafnium oxide or doped hafnium oxide.

According to an embodiment of the invention, in the ferroelectric capacitor structure, the dopant of the doped hafnium oxide may include zirconium (Zr), silicon (Si), strontium (Sr), yttrium (Y), lanthanum (La), germanium (Ge), or aluminum (Al).

According to an embodiment of the invention, in the ferroelectric capacitor structure, the thickness of the first nucleation layer may be 0.1 nanometer (nm) to 10 nm.

According to an embodiment of the invention, in the ferroelectric capacitor structure, the thickness of the first ferroelectric material layer may be 0.1 nm to 20 nm.

Based on the above description, in the ferroelectric capacitor structure according to the invention, the first nucleation layer is in contact with the first ferroelectric material layer, and the material of the first nucleation layer is β-W. Since the lattice misfit between the first nucleation layer (β-W) and the first ferroelectric material layer is small, an orthorhombic phase (o-phase) interface is easily formed, thereby effectively enhancing the remanent polarization of the first ferroelectric material layer.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional view of a ferroelectric capacitor structure according to some embodiments of the invention.

FIG. 1B is a cross-sectional view of a ferroelectric capacitor structure according to other embodiments of the invention.

FIG. 1C is a cross-sectional view of a ferroelectric capacitor structure according to other embodiments of the invention.

FIG. 1D is a cross-sectional view of a ferroelectric capacitor structure according to other embodiments of the invention.

FIG. 1E is a cross-sectional view of a ferroelectric capacitor structure according to other embodiments of the invention.

FIG. 1F is a cross-sectional view of a ferroelectric capacitor structure according to other embodiments of the invention.

FIG. 1G is a cross-sectional view of a ferroelectric capacitor structure according to other embodiments of the invention.

FIG. 2A is a perspective view of a ferroelectric capacitor structure according to other embodiments of the invention.

FIG. 2B is a perspective view of a ferroelectric capacitor structure according to other embodiments of the invention.

FIG. 2C is a perspective view of a ferroelectric capacitor structure according to other embodiments of the invention.

FIG. 2D is a perspective view of a ferroelectric capacitor structure according to other embodiments of the invention.

FIG. 2E is a perspective view of a ferroelectric capacitor structure according to other embodiments of the invention.

FIG. 2F is a perspective view of a ferroelectric capacitor structure according to other embodiments of the invention.

FIG. 2G is a perspective view of a ferroelectric capacitor structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

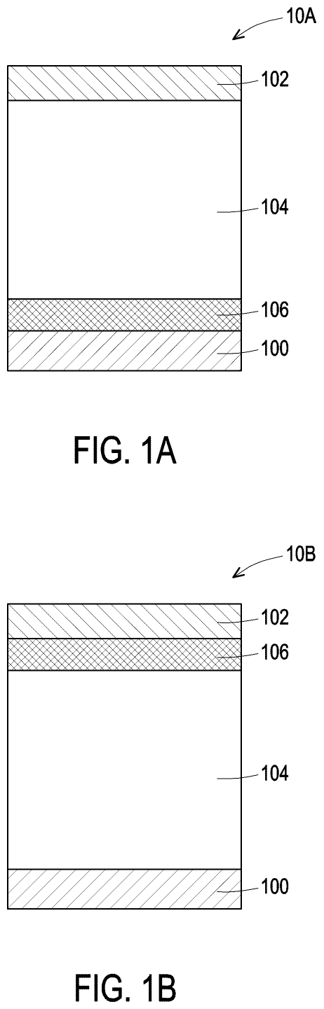

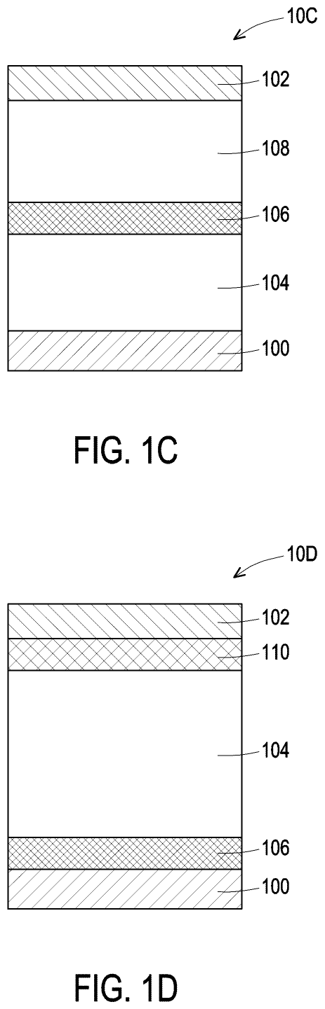

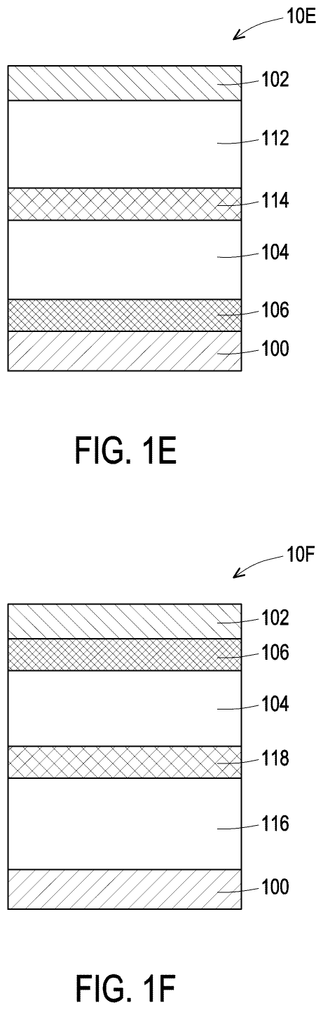

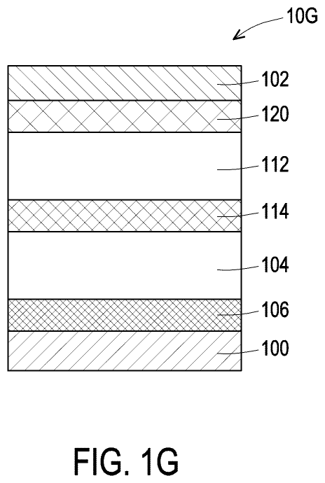

FIG. 1A is a cross-sectional view of a ferroelectric capacitor structure according to some embodiments of the invention.

Referring to FIG. 1A, a ferroelectric capacitor structure 10A includes an electrode 100, an electrode 102, a ferroelectric material layer 104, and a nucleation layer 106. In the present embodiment, the ferroelectric capacitor structure 10A may be a planar structure, but the invention is not limited thereto. In some embodiments, the material of the electrode 100 may include metal. In some embodiments, the material of the electrode 100 may include β-W, α-W, platinum, titanium, titanium nitride, aluminum, tungsten nitride, ruthenium, ruthenium oxide, tantalum, nickel, cobalt, copper, silver, or gold. In some embodiments, the lattice constant of β-W may be 5.06 Å, and the lattice constant of α-W may be 3.16 Å.

The electrode 102 is located on the electrode 100. In some embodiments, the material of the electrode 102 may include metal. In some embodiments, the material of the electrode 102 may include β-W, α-W, platinum, titanium, titanium nitride, aluminum, tungsten nitride, ruthenium, ruthenium oxide, tantalum, nickel, cobalt, copper, silver, or gold.

The ferroelectric material layer 104 is located between the electrode 100 and the electrode 102. The ferroelectric material layer 104 may be a single-layer structure or a multilayer structure. In some embodiments, the thickness of the ferroelectric material layer 104 may be 0.1 nm to 20 nm. In some embodiments, the material of the ferroelectric material layer 104 may include hafnium oxide, zirconium oxide, or a combination thereof. In some embodiments, the hafnium oxide may be undoped hafnium oxide or doped hafnium oxide. In some embodiments, the dopant of the doped hafnium oxide may include zirconium, silicon, strontium, yttrium, lanthanum, germanium, or aluminum.

The nucleation layer 106 is in contact with the ferroelectric material layer 104. The material of the nucleation layer 106 is β-W. In the present embodiment, the nucleation layer 106 may be located between the ferroelectric material layer 104 and the electrode 100, but the invention is not limited thereto. In some embodiments, the thickness of the nucleation layer 106 may be 0.1 nm to 10 nm.

Based on the above embodiments, in the ferroelectric capacitor structure 10A, the nucleation layer 106 is in contact with the ferroelectric material layer 104, and the material of the nucleation layer 106 is β-W. In this way, since the lattice misfit between the nucleation layer 106 (β-W) and the ferroelectric material layer 104 is small, an o-phase interface is easily formed, thereby effectively enhancing the remanent polarization of the ferroelectric material layer 104.

FIG. 1B is a cross-sectional view of a ferroelectric capacitor structure according to other embodiments of the invention.

Referring to FIG. 1A and FIG. 1B, the difference between the ferroelectric capacitor structure 10A of FIG. 1A and the ferroelectric capacitor structure 10B of FIG. 1B is as follows. In the ferroelectric capacitor structure 10B of FIG. 1B, the nucleation layer 106 may be located between the ferroelectric material layer 104 and the electrode 102. In addition, in FIG. 1A and FIG. 1B, the same or similar components are denoted by the same reference symbols, and the description thereof is omitted.

FIG. 1C is a cross-sectional view of a ferroelectric capacitor structure according to other embodiments of the invention.

Referring to FIG. 1A and FIG. 1C, the difference between the ferroelectric capacitor structure 10A of FIG. 1A and the ferroelectric capacitor structure 10C of FIG. 1C is as follows. In FIG. 1C, the ferroelectric capacitor structure 10C may further include a ferroelectric material layer 108. The ferroelectric material layer 108 is located between the ferroelectric material layer 104 and the electrode 102. The ferroelectric material layer 108 may be a single-layer structure or a multilayer structure. The nucleation layer 106 may be located between the ferroelectric material layer 104 and the ferroelectric material layer 108. The nucleation layer 106 may be in contact with the ferroelectric material layer 108. In this way, since the lattice misfit between the nucleation layer 106 (β-W) and the ferroelectric material layer 108 is small, an o-phase interface is easily formed, thereby effectively enhancing the remanent polarization of the ferroelectric material layer 108.

In some embodiments, the thickness of the ferroelectric material layer 108 may be 0.1 nm to 20 nm. In some embodiments, the material of the ferroelectric material layer 108 may include hafnium oxide, zirconium oxide, or a combination thereof. In some embodiments, the hafnium oxide may be undoped hafnium oxide or doped hafnium oxide. In some embodiments, the dopant of the doped hafnium oxide may include zirconium, silicon, strontium, yttrium, lanthanum, germanium, or aluminum. In addition, in FIG. 1A and FIG. 1C, the same or similar components are denoted by the same reference symbols, and the description thereof is omitted.

FIG. 1D is a cross-sectional view of a ferroelectric capacitor structure according to other embodiments of the invention.

Referring to FIG. 1A and FIG. 1D, the difference between the ferroelectric capacitor structure 10A of FIG. 1A and the ferroelectric capacitor structure 10D of FIG. 1D is as follows. In FIG. 1D, the ferroelectric capacitor structure 10D may further include a nucleation layer 110. The nucleation layer 110 may be located between the ferroelectric material layer 104 and the electrode 102. The nucleation layer 110 may be in contact with the ferroelectric material layer 104. The material of the nucleation layer 110 may be β-W. In this way, since the lattice misfit between the nucleation layer 110 (β-W) and the ferroelectric material layer 104 is small, an o-phase interface is easily formed, thereby effectively enhancing the remanent polarization of the ferroelectric material layer 104. In some embodiments, the thickness of nucleation layer 110 may be 0.1 nm to 10 nm. In addition, in FIG. 1A and FIG. 1D, the same or similar components are denoted by the same reference symbols, and the description thereof is omitted.

FIG. 1E is a cross-sectional view of a ferroelectric capacitor structure according to other embodiments of the invention.

Referring to FIG. 1A and FIG. 1E, the difference between the ferroelectric capacitor structure 10A of FIG. 1A and the ferroelectric capacitor structure 10E of FIG. 1E is as follows. In FIG. 1E, the ferroelectric capacitor structure 10E may further include a ferroelectric material layer 112 and a nucleation layer 114. The ferroelectric material layer 112 is located between the ferroelectric material layer 104 and the electrode 102. The ferroelectric material layer 112 may be a single-layer structure or a multilayer structure. The nucleation layer 114 may be located between the ferroelectric material layer 104 and the ferroelectric material layer 112. The nucleation layer 114 may be in contact with the ferroelectric material layer 104 and the ferroelectric material layer 112. The material of the nucleation layer 114 may be β-W. In this way, since the lattice misfit between the nucleation layer 114 (β-W) and the ferroelectric material layer 104 is small, an o-phase interface is easily formed, thereby effectively enhancing the between the nucleation layer 114 (β-W) and the ferroelectric material layer 112 is small, an o-phase interface is easily formed, thereby effectively enhancing the remanent polarization of the ferroelectric material layer 112.

In some embodiments, the thickness of the ferroelectric material layer 112 may be 0.1 nm to 20 nm. In some embodiments, the material of the ferroelectric material layer 112 may include hafnium oxide, zirconium oxide, or a combination thereof. In some embodiments, the hafnium oxide may be undoped hafnium oxide or doped hafnium oxide. In some embodiments, the dopant of the doped hafnium oxide may include zirconium, silicon, strontium, yttrium, lanthanum, germanium, or aluminum. In some embodiments, the thickness of the nucleation layer 114 may be 0.1 nm to 10 nm. In addition, in FIG. 1A and FIG. 1E, the same or similar components are denoted by the same reference symbols, and the description thereof is omitted.

FIG. 1F is a cross-sectional view of a ferroelectric capacitor structure according to other embodiments of the invention.

Referring to FIG. 1B and FIG. 1F, the difference between the ferroelectric capacitor structure 10B of FIG. 1B and the ferroelectric capacitor structure 10F of FIG. 1F is as follows. In FIG. 1F, the ferroelectric capacitor structure 10F may further include a ferroelectric material layer 116 and a nucleation layer 118. The ferroelectric material layer 116 is located between the ferroelectric material layer 104 and the electrode 100. The ferroelectric material layer 116 may be a single-layer structure or a multilayer structure. The nucleation layer 118 may be located between the ferroelectric material layer 104 and the ferroelectric material layer 116. The nucleation layer 118 may be in contact with the ferroelectric material layer 104 and the ferroelectric material layer 116. The material of the nucleation layer 118 may be β-W. In this way, since the lattice misfit between the nucleation layer 118 (β-W) and the ferroelectric material layer 104 is small, an o-phase interface is easily formed, thereby effectively enhancing the between the nucleation layer 118 (β-W) and the ferroelectric material layer 116 is small, an o-phase interface is easily formed, thereby effectively enhancing the remanent polarization of the ferroelectric material layer 116.

In some embodiments, the thickness of the ferroelectric material layer 116 may be 0.1 nm to 20 nm. In some embodiments, the material of the ferroelectric material layer 116 may include hafnium oxide, zirconium oxide, or a combination thereof. In some embodiments, the hafnium oxide may be undoped hafnium oxide or doped hafnium oxide. In some embodiments, the dopant of the doped hafnium oxide may include zirconium, silicon, strontium, yttrium, lanthanum, germanium, or aluminum. In some embodiments, the thickness of the nucleation layer 118 may be 0.1 nm to 10 nm. In addition, in FIG. 1B and FIG. 1F, the same or similar components are denoted by the same reference symbols, and the description thereof is omitted.

FIG. 1G is a cross-sectional view of a ferroelectric capacitor structure according to other embodiments of the invention.

Referring to FIG. 1E and FIG. 1G, the difference between the ferroelectric capacitor structure 10E of FIG. 1E and the ferroelectric capacitor structure 10G of FIG. 1G is as follows. In FIG. 1G, the ferroelectric capacitor structure 10G may further include a nucleation layer 120. The nucleation layer 120 may be located between the ferroelectric material layer 112 and the electrode 102. The nucleation layer 120 may be in contact with the ferroelectric material layer 112. The material of the nucleation layer 120 may be β-W. In this way, since the lattice misfit between the nucleation layer 120 (β-W) and the ferroelectric material layer 112 is small, an o-phase interface is easily formed, thereby effectively enhancing the remanent polarization of the ferroelectric material layer 112. In some embodiments, the thickness of the nucleation layer 120 may be 0.1 nm to 10 nm. In addition, in FIG. 1E and FIG. 1G, the same or similar components are denoted by the same reference symbols, and the description thereof is omitted.

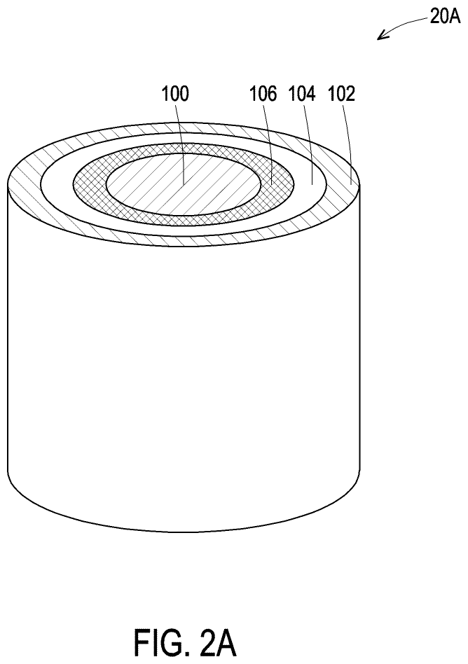

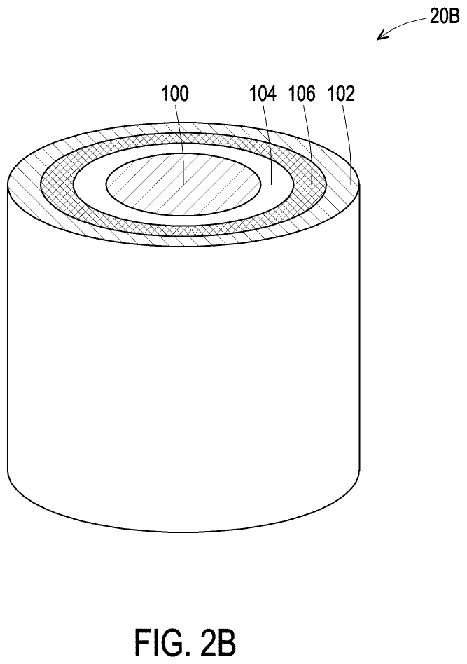

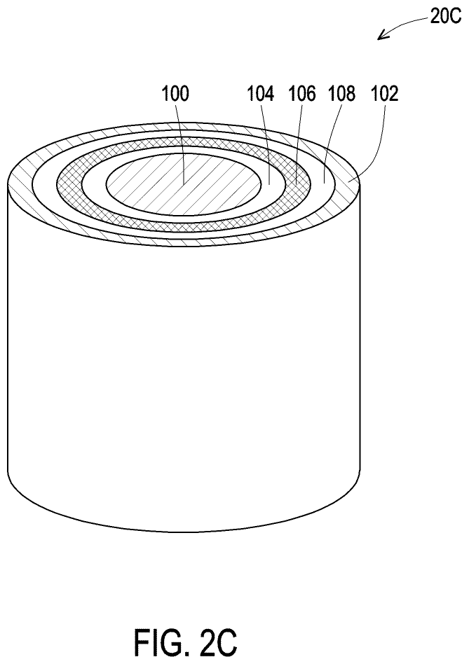

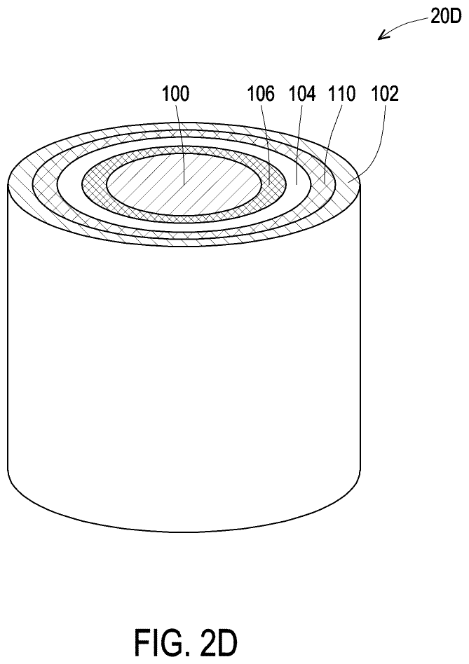

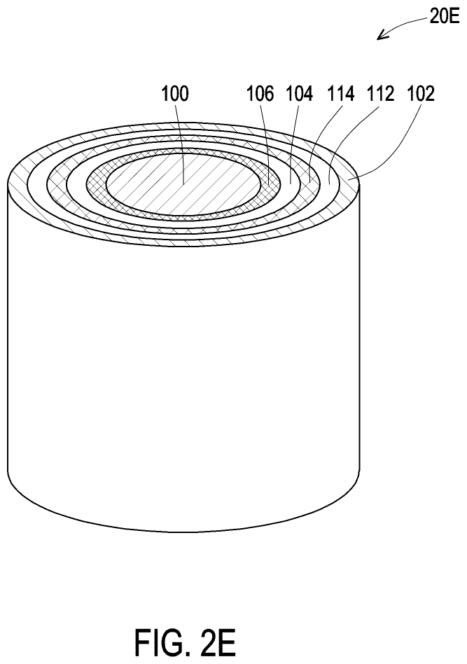

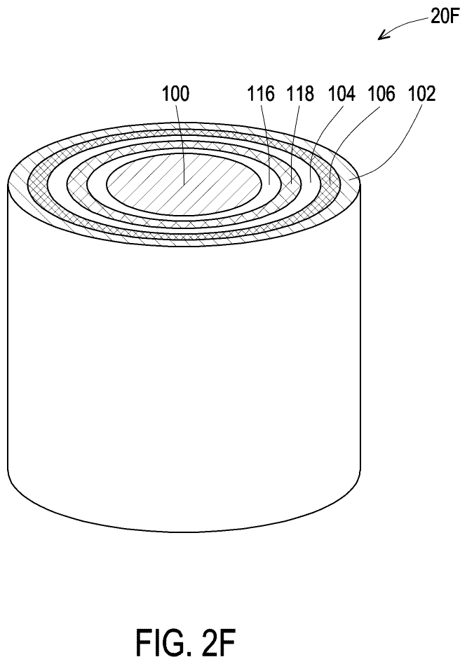

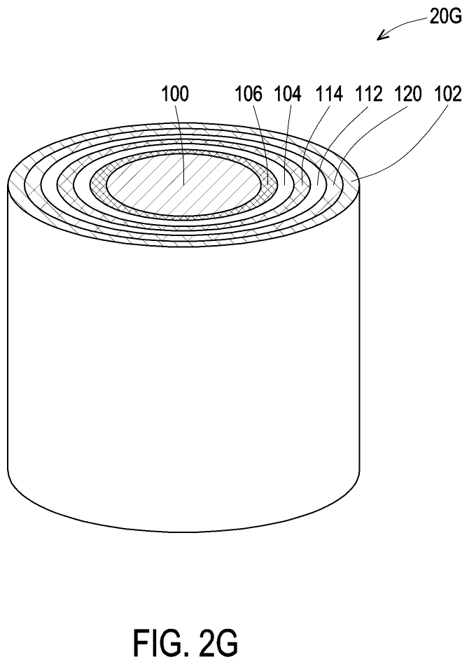

FIG. 2A is a perspective view of a ferroelectric capacitor structure according to other embodiments of the invention. FIG. 2B is a perspective view of a ferroelectric capacitor structure according to other embodiments of the invention. FIG. 2C is a perspective view of a ferroelectric capacitor structure according to other embodiments of the invention. FIG. 2D is a perspective view of a ferroelectric capacitor structure according to other embodiments of the invention. FIG. 2E is a perspective view of a ferroelectric capacitor structure according to other embodiments of the invention. FIG. 2F is a perspective view of a ferroelectric capacitor structure according to other embodiments of the invention. FIG. 2G is a perspective view of a ferroelectric capacitor structure according to other embodiments of the invention.

Referring to FIG. 1A to FIG. 1G and FIG. 2A to FIG. 2G, the arrangements of the components in the ferroelectric capacitor structure 20A of FIG. 2A to the ferroelectric capacitor structure 20G of FIG. 2G may respectively correspond to the arrangements of the components in the ferroelectric capacitor structure 10A of FIG. 1A to the ferroelectric capacitor structure 10G of FIG. 1G. The differences between the ferroelectric capacitor structure 10A of FIG. 1A to the ferroelectric capacitor structure 10G of FIG. 1G and the ferroelectric capacitor structure 20A of FIG. 2A to the ferroelectric capacitor structure 20G of FIG. 2G are as follows. The ferroelectric capacitor structure 10A to the ferroelectric capacitor structure 10G may be planar structures, and the ferroelectric capacitor structure 20A to the ferroelectric capacitor structure 20G may be a cylinder structures. In addition, in FIG. 1A to FIG. 1G and FIG. 2A to FIG. 2G, the same or similar components are denoted by the same reference symbols, and the description thereof is omitted.

In summary, in the ferroelectric capacitor structure of the aforementioned embodiments, the nucleation layer is in contact with the ferroelectric material layer, and the material of the nucleation layer is β-W. In this way, since the lattice misfit between the nucleation layer (β-W) and the ferroelectric material layer is small, an o-phase interface is easily formed, thereby effectively enhancing the remanent polarization of the ferroelectric material layer.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A ferroelectric capacitor structure, comprising:
a first electrode;
a second electrode located on the first electrode;
a first ferroelectric material layer located between the first electrode and the second electrode; and
a first nucleation layer in contact with the first ferroelectric material layer, wherein a material of the first nucleation layer is beta-tungsten (β-W).

2. The ferroelectric capacitor structure according to claim 1, wherein the first nucleation layer is located between the first ferroelectric material layer and the first electrode.

3. The ferroelectric capacitor structure according to claim 2, further comprising:
a second nucleation layer located between the first ferroelectric material layer and the second electrode and in contact with the first ferroelectric material layer, wherein a material of the second nucleation layer is β-W.

4. The ferroelectric capacitor structure according to claim 2, further comprising:
a second ferroelectric material layer located between the first ferroelectric material layer and the second electrode; and
a second nucleation layer located between the first ferroelectric material layer and the second ferroelectric material layer and in contact with the first ferroelectric material layer and the second ferroelectric material layer, wherein a material of the second nucleation layer is β-W.

5. The ferroelectric capacitor structure according to claim 4, further comprising:
a third nucleation layer located between the second ferroelectric material layer and the second electrode and in contact with the second ferroelectric material layer, wherein a material of the third nucleation layer is β-W.

6. The ferroelectric capacitor structure according to claim 1, wherein the first nucleation layer is located between the first ferroelectric material layer and the second electrode.

7. The ferroelectric capacitor structure according to claim 6, further comprising:
a second ferroelectric material layer located between the first ferroelectric material layer and the first electrode; and
a second nucleation layer located between the first ferroelectric material layer and the second ferroelectric material layer and in contact with the first ferroelectric material layer and the second ferroelectric material layer, wherein a material of the second nucleation layer is β-W.

8. The ferroelectric capacitor structure according to claim 1, further comprising:
a second ferroelectric material layer located between the first ferroelectric material layer and the second electrode, wherein the first nucleation layer is located between the first ferroelectric material layer and the second ferroelectric material layer and is in contact with the second ferroelectric material layer.

9. The ferroelectric capacitor structure according to claim 1, wherein the ferroelectric capacitor structure comprises a planar structure or a cylinder structure.

10. The ferroelectric capacitor structure according to claim 1, wherein a material of the first electrode comprises metal.

11. The ferroelectric capacitor structure according to claim 1, wherein a material of the first electrode comprises β-W, alpha-tungsten (α-W), platinum, titanium, titanium nitride, aluminum, tungsten nitride, ruthenium, ruthenium oxide, tantalum, nickel, cobalt, copper, silver, or gold.

12. The ferroelectric capacitor structure according to claim 1, wherein a material of the second electrode comprises metal.

13. The ferroelectric capacitor structure according to claim 1, wherein a material of the second electrode comprises β-W, α-W, platinum, titanium, titanium nitride, aluminum, tungsten nitride, ruthenium, ruthenium oxide, tantalum, nickel, cobalt, copper, silver, or gold.

14. The ferroelectric capacitor structure according to claim 1, wherein a material of the first ferroelectric material layer comprises hafnium oxide, zirconium oxide, or a combination thereof.

15. The ferroelectric capacitor structure according to claim 14, wherein the hafnium oxide comprises undoped hafnium oxide or doped hafnium oxide.

16. The ferroelectric capacitor structure according to claim 15, wherein a dopant of the doped hafnium oxide comprises zirconium, silicon, strontium, yttrium, lanthanum, germanium, or aluminum.

17. The ferroelectric capacitor structure according to claim 1, wherein a thickness of the first nucleation layer is 0.1 nm to 10 nm.

18. The ferroelectric capacitor structure according to claim 1, wherein a thickness of the first ferroelectric material layer is 0.1 nm to 20 nm.
